(19) United States
(12) Patent Application Publication
(10) Pub. No.: US 2003/0189904 A1
(43) Pub. Date: Oct. 9, 2003

(54) Sampling fractal internet protocol traffic with bounded error tolerance and response time

(76) Inventor: Jonathan Q. Li, Mountain View, CA (US)

Correspondence Address: AGILENT TECHNOLOGIES, INC., Legal Department, DL429, Intellectual Property Administration, P.O. Box 7599, Loveland, CO, 80537-0599, US

(21) Appl. No.: 10/116,429

(22) Filed: Apr. 4, 2002

(51) Int. Cl. G01R 31/08; G06F 11/00; G08C 15/00

(52) U.S. Cl. 370/252; 370/389

(57) ABSTRACT

A method and a system monitor fractal Internet Protocol traffic in a data network. The method determines a sampling interval and a sample size for sampling the data traffic such that the sampling has a predetermined response time and has a predetermined error tolerance that is bounded. The system employs the determined sampling interval and sample size for monitoring. The method comprises estimating a population variance from initial sampled data; estimating an index of self-similarity for the population; and computing the sampling interval and the sample size by simultaneously solving a pair of equations. The system comprises a probe that samples the traffic and generates sampled data; a processor, a memory, and a computer program stored in the memory and executed by the processor. The computer program comprises instructions that, when executed by the processor, determine the sampling interval and the sample size.

### TECHNICAL FIELD

The invention relates to digital communication networks. In particular, the invention relates to determining sampling parameters for data traffic within such a network.

### BACKGROUND ART

Monitoring data traffic flowing within a network and determining various parameters associated with that traffic during network operation is an important function in many modern communications networks. In particular, determining parameters associated with networks that carry Internet Protocol (IP) traffic is often critical to the proper operation and management of such networks. For example, multiple protocol label switching (MPLS) networks use traffic parameters, such as the total volume of packets transmitted between a source-destination pair within a specified time interval, to control the operation of and to optimize the performance of the network. In addition, Internet service providers (ISP) and ISP users often have a need for accurate information regarding traffic volume associated with a particular or selected Internet address.

Ideally, traffic parameters within an IP network are determined from direct measurements of packets captured by probes inserted into the network. Unfortunately, it is not always practical or even possible to directly measure packets. This is especially true in high-speed and/or high-volume networks where the traffic volume can often exceed a practical capacity of the probes and associated processors used to determine network parameters. In other cases such as optical networks, inserting probes can be impractical due to the nature of the network and the way data is transmitted therethrough. In such instances, sampling is typically employed to determine network parameters indirectly from a limited sample of network traffic.

A key element of accurately determining network parameters from data generated by sampling network traffic is a network traffic model. A network traffic model provides for, among other things, an incorporation of statistical characteristics of network traffic into a mathematical relationship. In particular, the mathematical relationship of the model relates sampling rates and/or sample sizes to sampling errors generated in the determined parameters. Typically, the model assumes that the network traffic is modeled by a specific random process having a specific distribution function. The characteristics of the random process are then employed in the model to relate error rates and sampling rates.

For example, historically Internet Protocol (IP) traffic often has been modeled as a Poisson process. Under such an assumption, inter-arrival times of packets are modeled as being exponentially distributed. Recent research by Willinger et al., “Self-Similarity Through High-Variability: Statistical Analysis of Ethernet LAN Traffic at the Source Level,” IEEE/ACM Transactions on Networking, Vol. 5, No. 1, 1997, pp. 71-86, has shown that IP traffic is highly self-similar and is better modeled as a fractal process. In particular, individual source-destination pairs within an IP network tend to exhibit inter-arrival times that follow a power-law decay distribution, while aggregates of many such source-destination pairs within a typical IP network can be modeled by fractional Brownian motion. The implication of the work by Willinger et al. and others is that IP traffic is better modeled as a fractal process than a Poisson process.

Accordingly, it would be advantageous to have a sampling approach for sampling IP traffic in a network that accounted for the observed fractal nature of IP traffic. Such a sampling approach would address a longstanding need in the area of determining traffic parameters in IP networks.

### SUMMARY OF THE INVENTION

The present invention determines characteristics of Internet Protocol (IP) traffic from sampled data of the traffic. In particular, the present invention determines a sampling interval and a sample size, given desired or predetermined unit interval, response time and error tolerance. The present invention incorporates self-similarity characteristics observed for IP traffic by employing a fractal model for the network IP traffic. According to the present invention, a sampling interval and a sample size are determined such that when sampling is performed on IP traffic, a sampling response time is achieved and sampling errors are bounded by a predetermined error tolerance.

In an aspect of the present invention, a method of sampling Internet Protocol traffic on a network is provided. The method comprises determining a sample size and sample interval such that when the sampling is performed on IP traffic a predetermined bounded error tolerance and a predetermined response time are achieved. The method of sampling employs initial sampled data taken from network traffic to estimate the particular characteristics of the network traffic.

In some embodiments, determining a sampling interval and a sample size comprises estimating a population variance from the initial sampled data. Estimating the population variance comprises computing a sample mean and computing a sample variance. The computed sample variance is used as the estimate of the population variance.

Determining a sampling interval and a sample size further comprises estimating an index of self-similarity for the population. Estimating the population index of self-similarity comprises calculating an autocorrelation function for the initial sampled data, determining regression coefficients using a natural logarithm of the autocorrelation function, and calculating the index of self-similarity from one of the determined regression coefficients.

Determining a sampling interval and a sample size further comprises computing the sampling interval and the sample size. The sampling interval and the sample size are computed by solving a simultaneous pair of equations for the sampling interval and the sample size. In a preferred embodiment, a first equation of the pair relates the response time to a product of the sampling interval, the sample size, and the unit interval. A second equation of the pair relates a function of the sampling interval, the sample size, the estimated population variance, and the self-similarity index to the error tolerance.

In another aspect of the invention, a system for monitoring data traffic in a network using sampling is provided. The system employs initial data sampled from the traffic to determine a sampling interval or rate and a sample size. The determined sampling interval and sample size facilitate further sampling of the traffic such that predetermined error tolerance and response time for sampling are achieved.

The system comprises a probe, a processor and a computer program executed by the processor. The probe samples the traffic and generates sampled data. The processor receives and processes the sampled data. The computer program comprises instructions that, when executed by the processor, determine the sampling interval and the sample size. The sampling interval and the sample size are determined from initial sampled data such that errors associated with the sampling are bounded by the predetermined error tolerance and the sampling has the predetermined response time. In a preferred embodiment, the instructions of the computer program implement the method of the present invention.

Advantageously, the present invention explicitly recognizes and accounts for the inherent fractal nature of aggregated source-destination traffic in modem IP networks. In particular, the present invention employs the self-similarity index of the data traffic to achieve a specified accuracy when sampling is used to measure traffic parameters. Moreover, the present invention provides for achieving a specified level of accuracy in a way that minimizes measurement time. Among other things, it is possible to perform a tradeoff between the accuracy and computational speed in the context of IP traffic using the present invention. Not only does the present invention deliver measurement accuracy but it also provides the measurements in a timely manner.

Certain embodiments of the present invention have other advantages in addition to and in lieu of the advantages described hereinabove. These and other features and advantages of the invention are detailed below with reference to the following drawings.

### BRIEF DESCRIPTION OF THE DRAWINGS

The various features and advantages of the present invention may be more readily understood with reference to the following detailed description taken in conjunction with the accompanying drawings, where like reference numerals designate like structural elements, and in which:

FIG. 1 illustrates a flow chart of a method of sampling Internet Protocol (IP) traffic that determines a sampling rate and a sample size according to the present invention.

FIG. 2 illustrates a flow chart of a preferred embodiment of estimating a population variance of the method of FIG. 1 according to the present invention.

FIG. 3 illustrates a flow chart of an embodiment of estimating a population self-similarity index of the method of FIG. 1 according to the present invention.

FIG. 4 illustrates a block diagram of a system for monitoring data traffic in a network using sampling according to the present invention.

### MODES FOR CARRYING OUT THE INVENTION

Sampling rate and sample size for sampling Internet Protocol (IP) traffic on a network are determined according to the present invention. The determined sampling rate 1/K or sampling interval K and sample size n are based on a given error tolerance r₀ and a given response time Tᵣ. When employed for sampling the IP traffic, the sampling rate 1/K and the sample size n provide that errors associated with the sampling are bounded by the error tolerance r₀. Moreover, using the sampling rate and the sample size n allows for achieving the sampling having the response time Tᵣ.

Herein, the terms ‘given’, ‘arbitrarily determined’, ‘desired’, and ‘predetermined’ are used interchangeably with respect to a value or a quantity that is determined in a manner that is independent of the present invention. Thus, a ‘predetermined’ or ‘given’ response time is a response time having a particular value that is chosen or determined independently and typically precedes the use of the present invention. Similarly, the terms ‘relative error tolerance’ and ‘error tolerance’ are used interchangeably to indicate a bound on errors associated with the use of the present invention. One of ordinary skill in the art is accustomed such interchangeability of terms with respect to sampling IP traffic on a network.

In an aspect of the present invention, a method 100 of sampling Internet Protocol (IP) traffic is provided. The method 100 of sampling comprises determining a sampling rate 1/K or sampling interval K and a sample size n such that when the sampling is performed on IP traffic, a predetermined bounded error tolerance and a predetermined response time are achieved. The sampling interval K and sample size n are determined with respect to a given unit interval T. The method 100 of sampling IP traffic employs initial sampled data Xᵢ, where i ranges from 1 to N, taken from network traffic.

Sampled data Xᵢ can be any data of interest in monitoring the performance of the traffic within a network. For example, the data Xᵢ might represent a time of arrival of packets in the network. Other examples of data Xᵢ include, but are not limited to, a proportion of a particular kind of IP packet, such as an FTP or HTTP packet, within a given time interval and a volume of IP packets going from and/or to a particular or specified IP address. Thus, for each kind of monitoring, the data Xᵢ typically has a different embodiment. For example, in monitoring the proportion of a particular kind of FTP packet, the data Xᵢ may represent a variable that takes on a value of zero if the incoming packet is not the particular kind of FTP packet and a value of one otherwise. Likewise, to measure the volume of IP packets going to a particular IP address, the data Xᵢ may represent a variable that takes on a value of zero if a packet is not going to the IP address, and if the packet is going to the IP address, the variable takes on a value equal to a size of the packet, for example. As such, the determined sampling interval K and sample size n produced by the method 100 generally depends on the specific type of data Xᵢ being sampled.

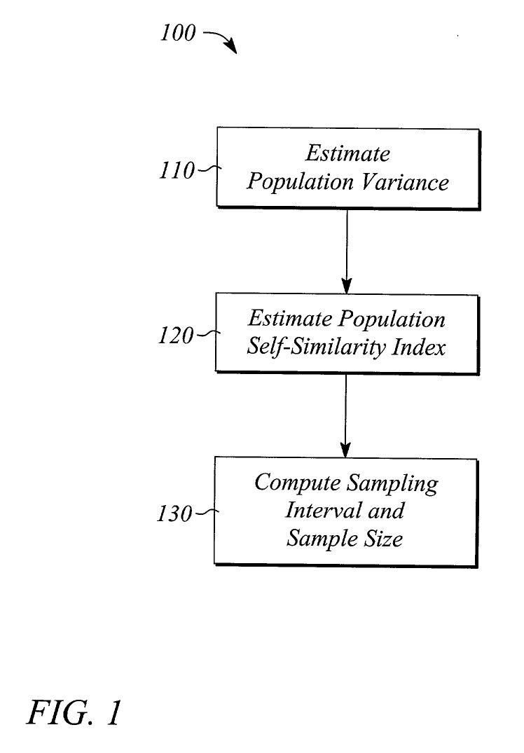

FIG. 1 illustrates a flow chart of the method 100 of sampling IP traffic according to the present invention. The method 100 of sampling IP traffic that determines a sampling interval K and a sample size n comprises estimating 110 a population variance σ² from the initial sampled data Xᵢ. As used herein, the sampling rate 1/K is an inverse of the sampling interval K. In a preferred embodiment, estimating 110 the population variance σ² comprises computing 112 a sample mean \hat{μ} and computing 114 a sample variance \hat{σ}². Estimating the population variance further comprises using 116 the computed 114 sample variance \hat{σ}² as an estimate of the population variance σ².

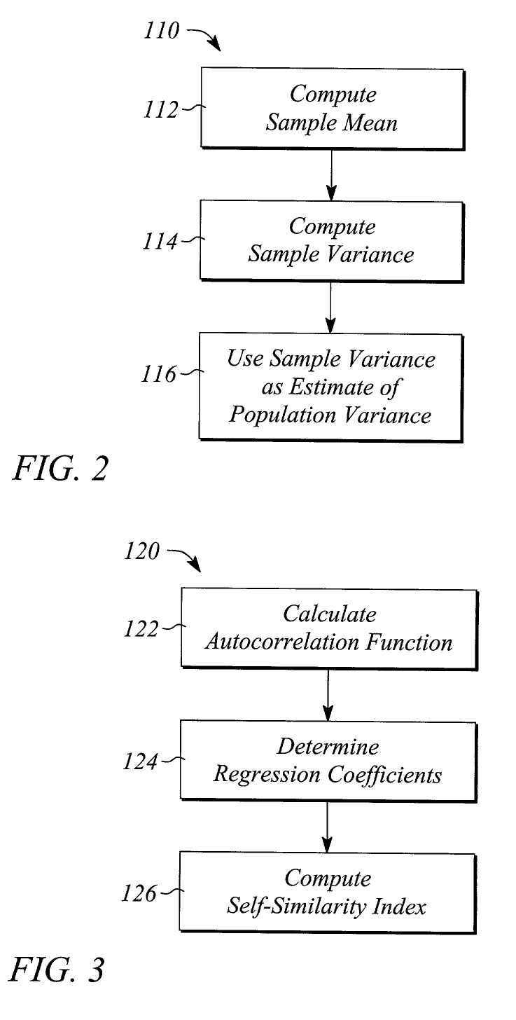

FIG. 2 illustrates a flow chart of the preferred embodiment of estimating 110 the population variance σ². The sample mean \hat{μ} may be computed 112 by employing equation (1).

$$\hat{μ} = \frac{1}{N} {\sum }_{i = 1}^{N} {X}_{i} \qquad ( 1 )$$

The sample variance \hat{σ}² may be computed 114 using equation (2) employing the computed 112 sample mean \hat{μ}.

$${\hat{σ}}^{2} = {\sum }_{i = 1}^{N} \frac{{( {X}_{i} - \hat{μ} )}^{2}}{N - 1} \qquad ( 2 )$$

Once the sample variance \hat{σ}² has been computed 114, it is assumed, according to the preferred embodiment, that the sample variance \hat{σ}² represents a good estimate of the population variance σ². Thus, the computed sample variance \hat{σ}² is used as the estimate of the population variance.

Generally, the assumption that the sample variance \hat{σ}² represents a good estimate of the population variance σ² is valid for an adequately large initial sample size N of initial data Xᵢ. Typically, samples sizes of N greater than 100 are preferred although some instances allow for smaller sample sizes N. One of ordinary skill in the art can readily determine a sample size N for a certain situation using conventional statistical analysis. Other approaches to estimating the population variance σ² including, but not limited to, using a statistical model of the data traffic, are known in the art and may be employed. All such other approaches to estimating the population variance σ² are within the scope of the present invention.

Referring back to FIG. 1, the method 100 further comprises estimating 120 an index of self-similarity H for the population. As mentioned hereinabove, actual IP network traffic is an aggregation of traffic generated by many source-destination pairs. As such, the aggregated IP traffic exhibits a self-similar or fractal characteristic. Mathematically speaking, aggregated IP streams are well represented by a fractal time series or process if individual source-destination pairs have long-tailed or power-law decay distributions. The present invention capitalizes on the realization that IP traffic can be accurately modeled as a fractal process through the estimation 120 and use of the population self-similarity index H for the traffic being sampled. The self-similarity index H is a key parameter for quantifying the statistical characteristics of a fractal process and is familiar to one of ordinary skill in the art.

FIG. 3 illustrates a flow chart of estimating 120 the population self-similarity index H. Estimating 120 the population index of self-similarity H comprises calculating 122 an autocorrelation function γ(t) for the initial data Xᵢ, where t is a time index associated with the initial data Xᵢ. In a preferred embodiment, the time index t takes on integer values between 1 and N and calculating the autocorrelation function γ(t) employs equation (3).

$$γ ( t ) = {\sum }_{i = 1}^{N - t} \frac{( {X}_{i} - \hat{μ} ) ( {X}_{i + t} - \hat{μ} )}{( N - t )} \qquad ( 3 )$$

One skilled in the art is familiar with the autocorrelation function γ(t) and its computation using sampled data.

Estimating 120 the population self-similarity index H further comprises determining 124 regression coefficients α and 62 that represent a best fit of a logarithm of the calculated 122 autocorrelation function to a logarithmic curve of the time index t as given by equation (4).

log(γ(t))=α·log(t)+β (4)

Any approach to finding the regression coefficients α and β equation (4) may be employed. Generally, an approach that produces a best fit in a least squares sense is preferred. A best fit in a least squares sense is defined as a choice of the regression coefficients α and β that minimizes a square of a difference between the right and left hand sides of equation (4). Thus in a preferred embodiment, a least squares curve-fitting approach is used to find the regression coefficients α and β. Those skilled in the art are familiar with least squares curve fitting, as well as a variety of other regression techniques, that may be used to find the regression coefficients α and β of equation (4). All such techniques are within the scope of the present invention.

Estimating 120 the index of self-similarity H further comprises calculating 126 the index H using equation (5).

$$H = \frac{( 2 - α )}{2} \qquad ( 5 )$$

The index H, thus determined, is an estimate of the population index of self-similarity since the autocorrelation function of equation (3) is a sample autocorrelation estimated from a finite number of samples. If a population autocorrelation function is available, the self-similar index H may be computed therefrom yielding the population self-similarity index H.

Again referring to FIG. 1, the method 100 further comprises computing 130 the sampling interval K and the sample size n. The sampling interval K and the sample size n are computed by simultaneously solving a pair of equations for the sampling interval K and the sample size n. In a preferred embodiment, a first equation of the pair is a total measurement time constraint and is given by equation (6).

Tᵣ=nKT (6)

Equation (6) for the total measurement time constraint employs the given or arbitrarily determined response time Tᵣ and relates the response time Tᵣ to a product of the sampling interval K, the sample size n, and the unit interval T. The unit interval T is also arbitrarily determined. The total measurement time constraint establishes a measurement response time for the sampling.

Typically, the unit interval T is one period of a clock signal of a processor used to sample the data Xᵢ. Thus, the unit interval T often represents a minimum sampling interval or minimum resolution of the data Xᵢ. In other cases, the unit interval T is dictated by a speed of a probe used to sample the data Xᵢ or a memory size and/or input/output transfer rate of the probe or processor. Thus in most monitoring situations according to the present invention, the unit interval T is determined by a physical and/or technological constraint of a monitoring system rather than a mathematical or statistical constraint. Similarly, the response time Tᵣ is highly dependent on the particular application, and depends on the data Xᵢ being monitored as well as other parameters of the network. One of ordinary skill in the art can readily determine an appropriate unit interval T and response time Tᵣ for a particular application or use of the present invention without undue experimentation.

A second equation of the pair represents an error constraint, also referred to as a ‘relative’ error constraint, and is given by equation (7).

$${r}_{0} = \frac{3.92 \sqrt{VAR ( K , n , H , σ )}}{\hat{μ}} \qquad ( 7 )$$

The relative error constraint employs the arbitrarily determined error tolerance r₀ and relates a function of the sampling interval K, the sample size n, the estimated 110 population variance σ², and the estimated 120 self-similarity index H to that of the error tolerance r₀. The error tolerance r₀ is also referred to as the ‘relative’ error tolerance r₀. The function VAR(K, n, σ, H) is preferably given by equation (8).

$$VAR ( K , n , H , σ ) = {σ}^{2} [ \frac{1}{n} + \frac{1}{{K}^{2 - 2 H}} \frac{1}{{n}^{2 - 2 H}} ] \qquad ( 8 )$$

Essentially, the constraint embodied in the relative error tolerance r₀ of equation (7) sets an upper bound on the errors associated with sampling.

As with the unit interval T and the response time Tᵣ, the relative error tolerance r₀ depends on a particular application of the present invention. Typically, the relative error tolerance is established either as a result of a specification or an industrial standard. For example, common industrial standards often employ a 95%, 99%, or 99.5% error tolerance level in monitoring. One skilled in the art can readily establish a relative error tolerance for a particular monitoring situation without undue experimentation.

In particular, the equation (7) that bounds the relative error tolerance is based on a definition of the relative error r as the ratio of the width of a 95% confidence interval to a value of the sampled data. By employing the well-known central limit theorem, the errors in the sampled data can be approximated by a Gaussian distribution and modeled using a Gaussian random variable. For a Gaussian random variable \overline{Y}, the 95% confidence interval is between \overline{Y}−1.96{square root over (VAR(Y)}) and \overline{Y}+1.96{square root over (VAR(Y)}). Therefore, the relative error tolerance is greater than or equal to the right hand side of equation (7) and a bound for the relative error tolerance r₀ is given by equation (7).

Techniques for solving two simultaneous equations having two unknowns are well known in the art. For example, the two equations may be combined together to form a single nonlinear equation. After combining, the single equation can be solved using a standard root-finding technique. Thus, equation (6) may be rearranged such that n=Tᵣ/(KT) which can then be substituted into equation (7) to produce the single combined nonlinear equation to be solved. A Newton-Raphson's method then may be employed to solve the combined equation. The Newton-Raphson's method is well known in the art of solving nonlinear equations. One skilled in the art is familiar with a variety of other techniques, all of which are within the scope of the present invention.

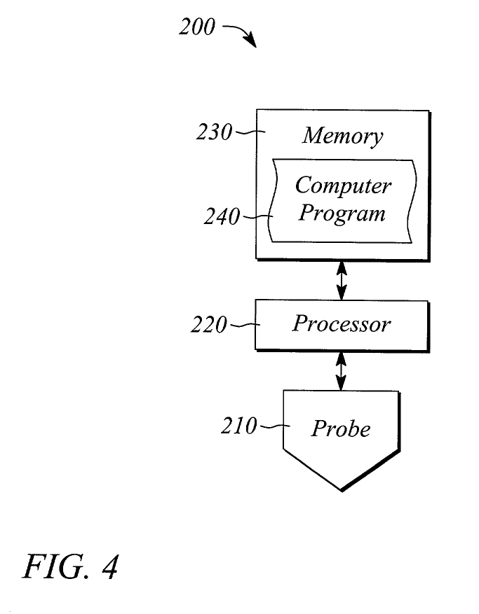

In another aspect of the invention, a system 200 for monitoring data traffic in a network using sampling is provided. FIG. 4 illustrates a block diagram of the system 200 for monitoring of the present invention. The system 200 employs initial data sampled from the traffic to determine a sampling interval K or sampling rate 1/K and a sample size n. The determined sampling interval K and sample size n facilitate further sampling of the traffic such that a relative error tolerance and a response time for sampling are achieved.

The system 200 for monitoring comprises a probe 210, a processor 220, a memory 230, and a computer program 240 stored in the memory 230 and executed by the processor 220. The probe 210 samples the traffic and generates the sampled data. The processor 220 receives and processes the sampled data. The computer program 240 comprises instructions that, when executed by the processor 220, determine the sampling interval K and the sample size n. The sampling interval K and the sample size n are determined from initial sampled data such that errors associated with the sampling are bounded by a relative error tolerance and the sampling has a predetermined response time. In a preferred embodiment, the instructions of the computer program 240 implement the method 100 of the present invention.

In particular, the instructions of the computer program 240 employ initial sample data of the traffic to compute a sample mean and a sample variance. From the sample variance, a population variance is estimated. In a preferred embodiment of the computer program 240, equations (1) and (2) are employed to compute the sample mean \hat{μ} and the sample variance \hat{σ}². Preferably, the sample variance \hat{σ}² is used as the estimate of the population variance σ². A self-similarity index H is computed by first determining an autocorrelation function γ(t) according to equation (3) for the sampled data and then finding regression coefficients α and β that fit a logarithm of the autocorrelation function γ(t) to a scaled and offset logarithm of an index variable t as given by equation (4). The self-similarity index H is preferably computed from the regression coefficient α using equation (5).

The computer program 240 determines the sampling interval K, or an inverse of the sampling interval K known as the sampling rate 1/K, and the sample size n. In the preferred embodiment, the sampling interval K and the sample size n are determined by simultaneously solving equations (6) and (7) using given values of the relative error tolerance r₀ and the response time Tᵣ. The given values of the relative error tolerance r₀ and the response time Tᵣ are input variables provided to the computer program 240 along with a value of the unit interval T. Given the discussion hereinabove including equations (1) through (8), one skilled in the art could readily generate such a computer program 240 without undue experimentation.

The probe 210 is specific for and adapted to the IP network being sampled. Typically, the probe 210 passively monitors or observes IP data packets or streams within the IP network. The probe 210 monitors a set or sequence of data packets from a connection of a plurality of physical connections within the network. For example, a probe 210 useful for an IEEE 802.3 Ethernet or Asynchronous Transfer Mode (ATM) network is a high impedance logic probe. The high impedance logic probe can be connected directly to one of the transmission wires of the network to collect copies of the data packets in the network without interfering with the normal flow of traffic. In another example for a different network, the probe 210 might be an inductively or capacitively coupled logic probe. In yet another example, the probe 210 might be built into the logic circuitry of nodes of the network, such that copies of raw data packets are fed to an output port on the node to be detected and processed. A variety of different probes 210 may be used on a single IP network as deemed appropriate. One skilled in the art would readily be able to determine an appropriate probe 210 to use for a specific IP network without undue experimentation.

The processor 220 and memory 230 may be any processor/memory combination that can execute the computer program 240. For example, the processor 220 and memory 230 may be a personal computer or workstation computer. In an alternate implementation, the processor 220 and memory may be built into and part of a specialized network monitoring system. In such an implementation, the processor may be a microprocessor while the memory 230 is a combination of random access memory (RAM) and read only memory (ROM). Alternatively, the processor 220 and memory 230 may be realized in such an implementation as part of an application specific integrated circuit (ASIC).

Thus, there has been described a novel method 100 of sampling IP traffic that determines a sample interval and a sample size. In addition, a system 200 for monitoring IP traffic using sampling has been described. It should be understood that the above-described embodiments are merely illustrative of the some of the many specific embodiments that represent the principles of the present invention. Clearly, those skilled in the art can readily devise numerous other arrangements without departing from the scope of the present invention.

What is claimed is:

1. A method of sampling Internet Protocol traffic on a network comprising:
determining a sample size and sample interval such that when the sampling is performed on IP traffic, a predetermined bounded error tolerance and a predetermined response time are achieved.

2. The method of claim 1 wherein determining the sampling interval or sample rate and a sample size comprises:
estimating a population variance from initial sampled data and a given unit interval;
estimating an index of self-similarity for the population; and
computing the sampling interval and the sample size by simultaneously solving a pair of equations for the sampling interval and the sample size.

3. The method of claim 2, wherein estimating a population variance comprises:
computing a sample mean of the initial sampled data;
computing a sample variance using the computed sample mean; and
using the computed sample variance as an estimate of the population variance.

4. The method of claim 3, wherein computing a sample mean comprises using equation (1).
$$\hat{μ} = \frac{1}{N} {\sum }_{i = 1}^{N} {X}_{i} \qquad ( 1 )$$
wherein \hat{μ} is the sample mean, and Xᵢ is the initial sampled data, where i ranges from 1 to N and where N is a sample size of the initial sampled data.

5. The method of claim 3, wherein computing a sample variance comprises using equation (2)
$${\hat{σ}}^{2} = {\sum }_{i = 1}^{N} \frac{{( {X}_{i} - \hat{μ} )}^{2}}{N - 1} \qquad ( 2 )$$
wherein \hat{σ}² is the sample variance, \hat{μ} is the sample mean, and Xᵢ is the initial sampled data, where i ranges from 1 to N and where N is a sample size of the initial sampled data.

6. The method of claim 3, wherein computing a sample variance comprises using a sample size N of greater than or equal to about 100 for the initial sampled data.

7. The method of claim 3, wherein computing a sample variance comprises using a sample size N of less than or equal to about 100 for the initial sampled data.

8. The method of claim 2, wherein estimating a population variance comprises using a statistical model of data from the Internet Protocol traffic.

9. The method of claim 2, wherein the Internet Protocol traffic is an aggregation of traffic generated by a plurality of source-destination pairs.

10. The method of claim 2, wherein estimating an index of self-similarity for the population comprises:
calculating an autocorrelation function for the initial sampled data, the autocorrelation function being a function of a time index associated with the initial sampled data;
determining regression coefficients that represent a mathematical best fit of a logarithm of the calculated autocorrelation function to a logarithmic curve of the time index; and
calculating the population index of self-similarity from one of the determined regression coefficients.

11. The method of claim 10, wherein calculating an autocorrelation function comprises employing equation (3)
$$γ ( t ) = {\sum }_{i = 1}^{N - t} \frac{( {X}_{i} - \hat{μ} ) ( {X}_{i + t} - \hat{μ} )}{( N - t )} \qquad ( 3 )$$
wherein γ(t) is the autocorrelation function; t is the time index having integer values between 1 and N; Xᵢ is the initial sampled data, where i ranges from 1 to N and where N is a sample size of the initial sampled data and \hat{μ} is a sample mean.

12. The method of claim 11, wherein the sample mean \hat{μ} is given by equation (1).
$$\hat{μ} = \frac{1}{N} {\sum }_{i = 1}^{N} {X}_{i} . \qquad ( 1 )$$

13. The method of claim 10, wherein determining regression coefficients comprises employing equation (4)
log(γ(t))=α·log(t)+β (4)
wherein γ(t) is the autocorrelation function; t is the time index having integer values between 1 and N; and α and β are the regression coefficients.

14. The method of claim 13, wherein the best fit is produced using a least squares approach, such that the regression coefficients are chosen to minimize a square of a difference between the right hand side and the and left hand side of equation (4).

15. The method of claim 10, wherein determining regression coefficients comprises using least squares curve fitting to determine the regression coefficients with the best fit.

16. The method of claim 10, wherein calculating the population index of self-similarity comprises using equation (5)
$$H = \frac{( 2 - α )}{2} \qquad ( 5 )$$
wherein H is the index of self-similarity for the population; and α is one of the determined regression coefficients.

17. The method of claim 2, wherein in computing the sampling interval and the sample size, a first equation of the pair represents a constraint on the predetermined response time for the sampling.

18. The method of claim 2, wherein in computing the sampling interval and the sample size, a second equation of the pair represents an error constraint, the error constraint setting an upper bound on errors associated with the sampling, the upper bound on errors being the predetermined bounded error tolerance.

19. The method of claim 2, wherein in computing the sampling interval and the sample size, a first equation of the pair represents a constraint on the predetermined response time for the sampling, the first equation being given by equation (6)
Tᵣ=nKT (6)
wherein Tᵣ is the predetermined response time; K is the sampling interval; n is the sample size; and T is the given unit interval.

20. The method of claim 19, wherein a second equation of the pair represents a relative error constraint, the second equation being given by equation (7)
$${r}_{0} = \frac{3.92 \sqrt{VAR ( K , n , H , σ )}}{\hat{μ}} \qquad ( 7 )$$
wherein r₀ is the predetermined bounded error tolerance; K is the sampling interval; n is the sample size; σ² is the estimated population variance; H is the estimated self-similarity index; and \hat{μ} is a sample mean.

21. The method of claim 20, wherein the sample mean \hat{μ} is computed using equation (1)
$$\hat{μ} = \frac{1}{N} {\sum }_{i = 1}^{N} {X}_{i} \qquad ( 1 )$$
wherein Xᵢ is the initial sampled data, where i ranges from 1 to N and where N is a sample size of the initial sampled data and wherein the estimated population variance σ² is computed using equation (2)
$${\hat{σ}}^{2} = {\sum }_{i = 1}^{N} \frac{{( {X}_{i} - \hat{μ} )}^{2}}{N - 1} \qquad ( 2 )$$
wherein \hat{σ}² is a sample variance, the sample variance being an estimate of the population variance σ².

22. The method of claim 20, wherein the function VAR(K, n, σ, H) is given by equation (8)
$$VAR ( K , n , H , σ ) = {σ}^{2} [ \frac{1}{n} + \frac{1}{{K}^{2 - 2 H}} \frac{1}{{n}^{2 - 2 H}} ] . \qquad ( 8 )$$

23. A system for monitoring data traffic in a network using sampling comprises:
a probe that samples the data traffic and generates sampled data;
a processor that processes the sampled data;
a memory; and
a computer program stored in the memory and executed by the processor, the computer program comprising instructions that, when executed by the processor, determine a sampling interval and a sample size for the sampled data, the sampling interval and the sample size being determined from initial sampled data, such that errors associated with the sampling are bounded by an error tolerance and the sampling has a predetermined response time.

24. The system of claim 23, wherein the instructions that determine a sampling interval and a sample size comprise:
estimating a population variance from the initial sampled data, the initial data being sampled from a population of data with respect to a given unit interval;
estimating an index of self-similarity for the population; and
computing the sampling interval and the sample size by simultaneously solving a pair of equations for the sampling interval and the sample size.

25. The system of claim 24, wherein the instructions that estimate a population variation from the initial sampled data comprise:
computing a sample mean of the initial sampled data;
computing a sample variance using the computed sample mean; and
using the computed sample variance as an estimate of the population variance.

26. The system of claim 23, wherein the data traffic is Internet Protocol (IP) traffic, the IP traffic being an aggregation of traffic generated by a plurality of source-destination pairs, such that the aggregated traffic exhibits a self-similar, fractal characteristic.

27. The system of claim 24, wherein instructions that estimate an index of self-similarity for the population comprises:
calculating an autocorrelation function for the initial sampled data, the autocorrelation function being a function of a time index associated with the initial sampled data;
determining regression coefficients that represent a mathematical best fit of a logarithm of the calculated autocorrelation function to a logarithmic curve of the time index; and
calculating the population index of self-similarity from one of the determined regression coefficients.

28. The system of claim 27, wherein determining regression coefficients comprises using least squares curve-fitting to determine the regression coefficients with the best fit.

29. The system of claim 24, wherein a first equation of the pair represents a constraint on the predetermined response time for the sampling; and wherein a second equation of the pair represents an error constraint, the error constraint setting an upper bound on errors associated with the sampling, the upper bound being the error tolerance.

30. A system for monitoring data traffic in a network using sampling comprising:
a probe that samples the data traffic and generates sampled data;
a processor that processes the sampled data;
a memory: and
a computer program stored in the memory and executed by the processor, the computer program comprising instructions that, when executed by the processor, determine a sampling interval and a sample size for the sampling, the determined sampling interval and sample size facilitating further sampling of the data traffic, such that an error tolerance and a response time for the sampling are achieved.

31. The system of claim 30, wherein the probe is one or more of a high impedance logic probe, an inductively or capacitively coupled logic probe, and a probe that is built into logic circuitry of nodes of the network.

32. The system of claim 30, wherein the processor and the memory are one or more of combined as a personal computer or a workstation computer, built into and part of a specialized network monitoring system, and implemented as part of an application specific integrated circuit (ASIC).
